(19) United States
(12) Patent Application Publication
(10) Pub. No.: US 2025/0020964 A1
(43) Pub. Date: Jan. 16, 2025

(54) DISPLAY PANEL AND DISPLAY DEVICE

(71) Applicant: TCL CHINA STAR OPTOELECTRONICS TECHNOLOGY CO., LTD., Shenzhen (CN)

(72) Inventor: He ZHAO, Shenzhen (CN)

(73) Assignee: TCL CHINA STAR OPTOELECTRONICS TECHNOLOGY CO., LTD., Shenzhen (CN)

(21) Appl. No.: 18/902,432

(22) Filed: Sep. 30, 2024

Related U.S. Application Data
(63) Continuation of application No. 17/431,125, filed on Aug. 13, 2021, now Pat. No. 12,140,841.

(30) Foreign Application Priority Data
Mar. 4, 2020 (CN) 202010145410.0

(51) Int. Cl. G02F 1/1362; G02F 1/1343; G02F 1/1368; H01L 27/12

(52) U.S. Cl. CPC G02F 1/136286; G02F 1/13439; G02F 1/136209; G02F 1/136222; G02F 1/1368; H01L 27/124; H01L 27/1255

(57) ABSTRACT

The present disclosure provides a display panel and a display device. The display device includes the display panel. The display panel includes a first substrate and a second substrate opposite to the first substrate. The first substrate includes a first base substrate and a plurality of the data lines arranged on the first base substrate. The second substrate includes a second base substrate. The display panel further includes a black matrix disposed on one of the first base substrate and the second base substrate. An orthographic projection of the data lines on the first base substrate and an orthographic projection of the black matrix on the first base substrate do not overlap.

### CROSS-REFERENCE TO RELATED APPLICATION

This application is a continuation application of U.S. patent application Ser. No. 17/431,125, filed on Aug. 13, 2021, which is a US national phase application based upon an International Application No. PCT/CN2020/140598, filed on Dec. 29, 2020, which claims priority to Chinese Patent Application No. 202010145410.0, filed on Mar. 4, 2020. The disclosures of the aforementioned applications are incorporated herein by reference in their entireties.

### FIELD OF INVENTION

The present disclosure relates to the field of display technologies, in particular to a display panel and a device.

### BACKGROUND OF INVENTION

The higher the resolution of a display panel, the higher the clarity of a screen.

The resolution of the display panel is also a precision of the screen. The resolution is proportional to a number of pixels in the display panel. The more pixels in the screen, the clearer the images. However, it is limited by a structure of an existing display panel, and the resolution cannot be effectively improved.

### SUMMARY

The present disclosure provides a display panel. The display panel includes a first substrate and a second substrate opposite to the first substrate. The first substrate includes a first base substrate and a plurality of the data lines arranged on the first base substrate. The second substrate includes a second base substrate. The display panel further includes a black matrix disposed on one of the first base substrate and the second base substrate. An orthographic projection of the data lines on the first base substrate and an orthographic projection of the black matrix on the first base substrate do not overlap.

The present disclosure provides a display device including the display panel.

### DESCRIPTION OF DRAWINGS

FIG. 1 is a top view of a display panel in the prior art.

FIG. 2 is a cross-sectional view of the display panel in FIG. 1 along a line B-B′.

FIG. 3 is a cross-sectional view of the display panel in FIG. 1 along a line A-A′.

FIG. 4 is a top view of a display panel of an embodiment of the present disclosure.

FIG. 5 is a cross-sectional view of the display panel in FIG. 4 along a line D-D′.

FIG. 6 is a cross-sectional view of the display panel in FIG. 4 along a line C-C′.

FIG. 7 is a cross-sectional view of the display panel in FIG. 4 along a line E-E′.

### DETAILED DESCRIPTION OF EMBODIMENTS

A description of following embodiments refers to accompanying drawings to illustrate specific embodiments that can be implemented by the present disclosure. Direction terms mentioned in the present disclosure, such as “up”, “down”, “front”, “back”, “left”, “right”, “in”, “out”, “side”, etc., only refer to directions of the accompanying drawings. Therefore, the used directional terms are configured to explain and understand the present disclosure, not to limit the present disclosure. In the drawings, units with similar structures are indicated by the same reference numerals.

Terms, such as “first”, “second”, etc., in the specification and claims of this application and the above-mentioned drawings are used to distinguish different objects, rather than to describe a specific order. In addition, terms, such as “including” and “having” and any variations of them, are intended to cover a non-exclusive inclusion.

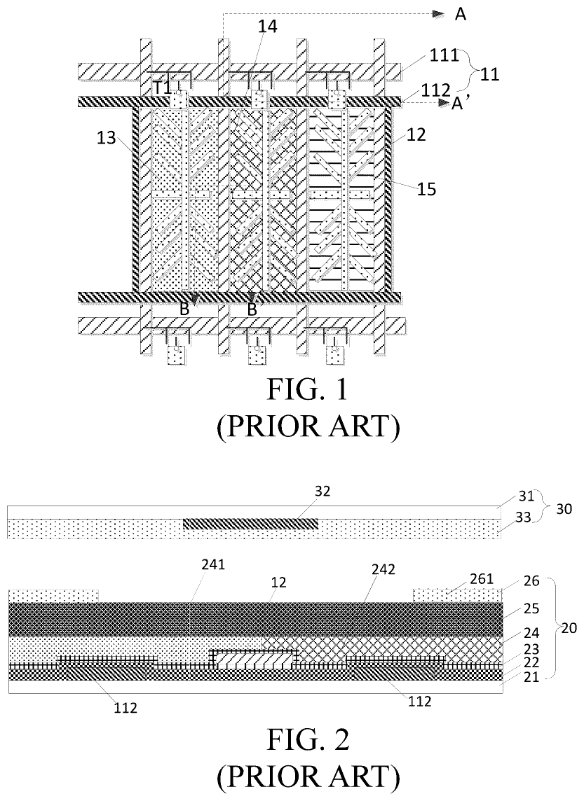

As shown in FIG. 1 to FIG. 3, an existing display panel includes a plurality of scan lines 111 and a plurality of data lines 12. The data lines 12 and scan lines 111 define a plurality of pixels, such as a pixel 13, a pixel 14, and a pixel 15. A gate of a thin film transistor T1 is connected to the scan line 111, a source of the thin film transistor T1 is connected to the data line 12, and a drain of the thin film transistor T1 is connected to a first plate 112 of a storage capacitor and a pixel electrode 261.

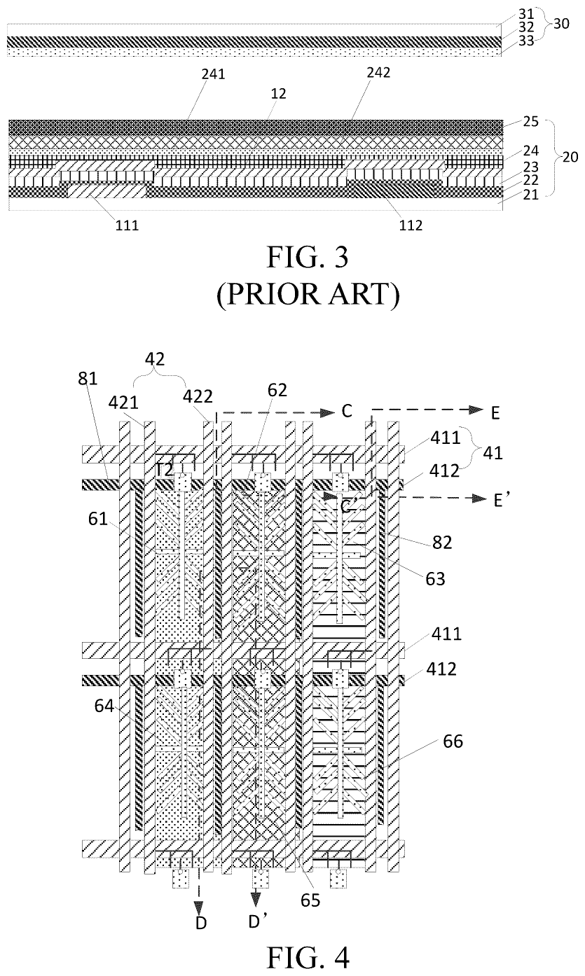

Referring to FIG. 2 and FIG. 3, a cross-sectional structure of the existing display panel includes a first substrate 20 and a second substrate 30.

The first substrate 20 includes a first base substrate 21, a first metal layer 11, an insulating layer 22, a second metal layer (not shown in the drawings), a passivation layer 23, a color photoresist layer 24, a protective layer 25, and a first transparent conductive layer 26.

The color photoresist layer 24 is disposed on the passivation layer 23. The color photoresist layer 24 includes a plurality of color film photoresists, such as a red color film 241, a green color film 242, and a blue color film.

The second substrate 30 includes a second base substrate 31, a black matrix 32, and a second transparent conductive layer 33. Referring to FIG. 3, all of the data lines 12 are covered with the black matrix 32. If a number of the data lines 12 is increased, an aperture will decrease.

Referring to FIG. 4 to FIG. 7. FIG. 4 is a top view of a display panel of an embodiment of the present disclosure.

Referring to FIG. 4 to FIG. 7, in the top view, the display panel of this embodiment includes a plurality of pixels, such as a pixel 61, a pixel 62, a pixel 63, a pixel 64, a pixel 65, and a pixel 66. The plurality of pixels form a pixel matrix, that is, the display panel includes a plurality of columns of pixels or a plurality of rows of pixels.

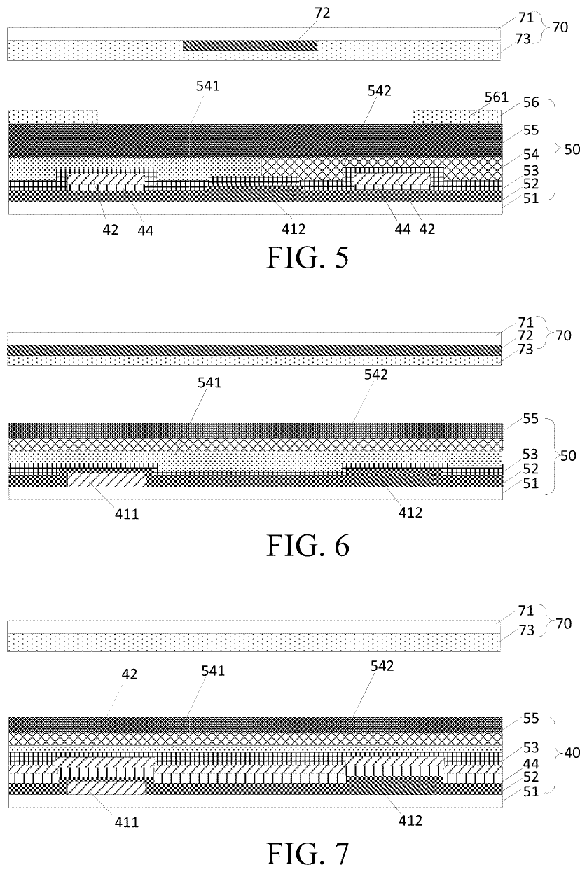

Referring to FIG. 5, the display panel of this embodiment includes a first substrate 50 and a second substrate 70.

The first substrate 50 includes a first base substrate 51, a first metal layer 41, an insulating layer 52, a semiconductor layer 44, a second metal layer (not shown in the drawings), a passivation layer 53, a color photoresist layer 54, a protective layer 55, and a first transparent conductive layer 56.

The first metal layer 41 is disposed on the first base substrate 51. The first metal layer 41 includes a plurality of scan lines 411 and a plurality of first metal portions 412. The first metal portions 412 are configured to form first plates of storage capacitors. Referring to FIG. 4, the first metal portion 412 includes a first sub-portion 81 arranged along a first direction and a plurality of second sub-portions 82 arranged along a second direction. One end of each second sub-portion 82 is connected to the first sub-portion 81. The first direction is parallel to the scan lines 411. The second direction is parallel to a data line 42.

The insulating layer 52 is disposed on the first metal layer 41, and the insulating layer 52 can be made of SiNₓ, SiOₓ, or other materials.

The semiconductor layer 44 is disposed between the first metal layer 41 and the second metal layer. The semiconductor layer 44 is configured to form channels of thin film transistors.

The second metal layer is disposed on the first metal layer 41. The second metal layer includes plurality of the data lines 42. One of the second sub-portions 82 is disposed between two adjacent data lines 42. In order to save a number of masks and simplify a manufacturing process, in one embodiment, the data lines 42 are disposed above the semiconductor layer 44. In one embodiment, in order to further improve a transmittance, the data lines 42 and the adjacent second sub-portions 82 are arranged at intervals. In order to further improve the transmittance, each of two sides of each pixel is provided with one of the second sub-portions 82. An orthographic projection of the second sub-portion 82 on the first base substrate 51 partially overlaps an orthographic projection of an edge of each of two sides of a corresponding color film photoresist on the first base substrate 51. Materials of the second metal layer and the first metal layer 41 may include at least one of Mo, Al, Ti, or Cu. In one embodiment, a width of the data line 42 may range from 1.5 μm to 3 μm. By reducing the width of the data line, a gap between the data line and the second sub-portion is increased, thereby further increasing the aperture. Since the first metal portion is disposed between two adjacent data lines, a loss of the aperture caused by the increased data lines can be compensated by the gap between the first metal portions and the data lines, so as to avoid affecting the aperture.

The passivation layer 53 is disposed on the second metal layer. Material of the passivation layer 53 may include at least one of SiO₂, SiNₓ, or SiON.

The color photoresist layer 54 is disposed on the passivation layer 53. The color photoresist layer 54 includes a plurality of color film photoresists, such as a red color film 541, a green color film 542, and a blue color film. Referring to FIG. 5, each the first metal portion 412 corresponds to a position of two adjacent color film photoresists. The first metal portions 412 cover abutting positions of two adjacent color film photoresists. Each side of two side of column of color film photoresists is provided with one of the data lines. For example, taking the red color films in a first column as an example, a data line 421 and a data line 422 are disposed on both sides of the color film photoresists in the first column, and the color film photoresists in other columns are the same.

The protective layer 55 is disposed on the color photoresist layer 54. Material of the protective layer 55 may include at least one of SiO₂, SiNₓ, or SiON.

The first transparent conductive layer 56 is disposed on the color photoresist layer 54. The transparent conductive layer 56 includes a plurality of pixel electrodes 561. The pixel electrodes 561 correspond to the color film photoresists. In one embodiment, a storage capacitor is formed between the pixel electrode 561 and the first metal portion 412. Material of the first transparent conductive layer 56 may be indium tin oxide.

The second substrate 70 is disposed opposite to the first substrate 50. The second substrate 70 includes a second base substrate 71, a black matrix 72, and a second transparent conductive layer 73, and the black matrix 72 and the second transparent conductive layer 73 are sequentially disposed under the second base substrate 71. Material of the second transparent conductive layer 73 may be indium tin oxide.

Referring to FIG. 6 and FIG. 7, the black matrix 72 corresponds to the abutting positions of two adjacent color film photoresists. In one embodiment, in order to improve the transmittance of the display panel, an orthographic projection of the data lines 42 on the first base substrate 51 and an orthographic projection of the black matrix 72 on the first base substrate 51 do not overlap. That is, the black matrix 72 is not covered on the data lines 42. In FIG. 7, taking one data line as an example for illustration, it is understandable that the other data lines are not covered with black matrix.

The second transparent conductive layer 73 is configured to form common electrodes.

Two adjacent pixels in each column of pixels are alternately connected to the data lines disposed on two sides of the column of pixels. For example, the first pixel 61 in the first column of pixels is connected to the data line 421 on the left, the second pixel 64 in the first column of pixels is connected to the data line 422 on the right, and the other pixels are similar. In FIG. 4, only 6 pixels are shown, but it does not limit the present disclosure.

Each row of pixels corresponds to one scan line 411. The pixel includes a thin film transistor T2. A gate of the thin film transistor T2 is connected to a corresponding scan line 411. A source of the thin film transistor T2 is connected to a corresponding data line 42. A drain of the thin film transistor T2 is connected to the first metal portion 412 and the pixel electrode 561.

The display panel of this embodiment may be a liquid crystal display panel, and the display panel may further include a liquid crystal layer. The liquid crystal layer is disposed between the first substrate 50 and the second substrate 70.

It can be understood that a structure of the display panel of the present disclosure is not limited to this. For example, in other embodiments, the color photoresist layer is disposed on the second substrate. In other embodiments, the black matrix is disposed on the first substrate. For example, the black matrix is disposed on the color photoresist layer or on a same layer as the color photoresist layer.

Due to an existing panel structure is adjusted, a number of data lines and scan lines has been increased at the same time, thereby increasing a number of pixels, and increasing a resolution. In addition, because the second sub-portion is disposed between two adjacent data lines, the aperture can be increased through the gap between the data line and the second sub-portion, thereby preventing a low aperture due to an increase of the data lines.

The present disclosure also provides a display device, which includes any of the above-mentioned display panels. The display device may also include a backlight module.

The display panel and device of the present disclosure include the first base substrate. The first metal layer is disposed on the first base substrate. The first metal layer includes the plurality of scan lines and the plurality of first metal portions. The first metal portions are configured to form the first plates of the storage capacitors. The first metal portion includes the plurality of second sub-portions arranged along the second direction. The second direction is parallel to the data lines. The second metal layer is disposed on the first metal layer. The second metal layer includes the plurality of data lines. The second sub-portion is disposed between two adjacent data lines. The data lines and the adjacent second sub-portions are arranged at intervals. In the top view, the display panel includes the plurality of columns of pixels or the plurality of rows of pixels. Each of two sides of each of the columns of pixels is provided with one of the data lines. The first transparent conductive layer is disposed on the second metal layer and includes the plurality of pixel electrodes. The second substrate is disposed opposite to the first substrate, and includes the second base substrate. The second transparent conductive layer is disposed under the second base substrate. Since the existing panel structure is adjusted, the number of pixels has been increased, and the resolution has been improved.

In summary, although the present disclosure has been disclosed as above in preferred embodiments, the above preferred embodiments are not intended to limit the present disclosure. Those of ordinary skill in the art can make various changes and modifications without departing from a spirit and a scope of the present disclosure. Therefore, the protection scope of the present disclosure is subject to a scope defined by the claims.

What is claimed is:

1. A display panel, comprising:
a first substrate, comprising:
a first base substrate; and
a plurality of the data lines arranged on the first base substrate;
a second substrate opposite to the first substrate and comprising a second base substrate; and
a black matrix disposed on one of the first base substrate and the second base substrate,
wherein an orthographic projection of the data lines on the first base substrate and an orthographic projection of the black matrix on the first base substrate do not overlap.

2. The display panel according to claim 1, wherein the first substrate comprises a first metal layer disposed on the first base substrate and a second metal layer disposed on one side of the first metal layer facing away from the first base substrate, the first metal layer comprises a plurality of scan lines, and the second metal layer comprises the plurality of the data lines.

3. The display panel according to claim 2, further comprising a semiconductor layer disposed between the first metal layer and the second metal layer, wherein the semiconductor layer is disposed under the data lines.

4. The display panel according to claim 2, wherein the display panel comprises a plurality of columns of pixels or a plurality of rows of pixels defined by the scan lines and the data lines, each of two opposite sides of each column of pixels is provided with one of the data lines, and two adjacent pixels in each column of pixels are alternately connected to the data lines disposed on the two opposite sides of the column of pixels.

5. The display panel according to claim 4, wherein each row of pixels corresponds to one of the scan lines, each of the pixels comprises a thin film transistor, a gate of the thin film transistor is connected to a corresponding one of the scan lines, a source of the thin film transistor is connected to a corresponding one of the data lines, and a drain of the thin film transistor is connected to one of the first metal portions and one pixel electrode of the display panel.

6. The display panel according to claim 2, wherein the first metal layer further comprises a plurality of first metal portions configured to form first plates of storage capacitors.

7. The display panel according to claim 6, wherein each of the first metal portions comprises a plurality of second sub-portions arranged along a second direction, the second direction is parallel to the data lines.

8. The display panel according to claim 7, wherein the display panel comprises a plurality of columns of pixels or a plurality of rows of pixels defined by the scan lines and the data lines, one of the second sub-portions and two of the data lines are provided between adjacent columns of pixels, and the one of the second sub-portions is disposed between the two of the data lines.

9. The display panel according to claim 8, wherein the one of the second sub-portions and the two of the data lines are arranged at intervals.

10. The display panel according to claim 7, wherein each of the first metal portions further comprises a first sub-portion arranged along a first direction, the first direction is parallel to the scan lines, and one end of each of the second sub-portions is connected to the first sub-portion of a same one of the first metal portions.

11. The display panel according to claim 7, wherein the first substrate further comprises a color photoresist layer disposed on the second metal layer, and the black matrix is disposed on one of the second base substrate and one side of the color photoresist layer facing away from the first base substrate.

12. The display panel according to claim 11, wherein the color photoresist layer comprises a plurality of color film photoresists, and the first metal portions correspond to abutting positions of adjacent ones of the plurality of color film photoresists, and the black matrix corresponds to the abutting positions.

13. The display panel according to claim 12, wherein an orthographic projection of the plurality of second sub-portions on the first first base substrate partially overlaps opposite edges of an orthographic projection of the plurality of color film photoresists on the first first base substrate.

14. The display panel according to claim 6, wherein the first substrate further comprises a first transparent conductive layer disposed on the second metal layer, and the first transparent conductive layer comprises a plurality of pixel electrodes configured to form second plates of the storage capacitors.

15. The display panel according to claim 1, wherein the second substrate further comprises a second transparent conductive layer disposed on one side of the second base substrate facing the first substrate.

16. The display panel according to claim 15, wherein the second transparent conductive layer is configured to form a common electrode.

17. The display panel according to claim 15, wherein the black matrix is disposed on the first base substrate or between the second base substrate and the second transparent conductive layer.

18. The display panel according to claim 1, wherein a width of one of the data lines ranges from 1.5 micrometers to 3 micrometers.

19. The display panel according to claim 1, further comprising a liquid crystal layer disposed between the first substrate and the second substrate.

20. A display device, comprising a display panel, and the display panel comprising:
a first substrate, comprising:
a first base substrate; and
a plurality of the data lines arranged on the first base substrate;
a second substrate opposite to the first substrate and comprising a second base substrate; and
a black matrix disposed on one of the first base substrate and on the second base substrate,
wherein an orthographic projection of the data lines on the first base substrate and an orthographic projection of the black matrix on the first base substrate do not overlap.
